(19) United States
(12) Patent Application Publication
(10) Pub. No.: US 2012/0304916 A1
(43) Pub. Date: Dec. 6, 2012

(54) METHOD OF PRODUCING SILICON CARBIDE SINGLE CRYSTAL

(75) Inventor: Tomokazu Ishii, Susono-shi (JP)

(73) Assignee: TOYOTA JIDOSHA KABUSHIKI KAISHA, Toyota-shi, Aichi-ken (JP)

(21) Appl. No.: 13/577,500

(22) PCT Filed: Feb. 17, 2011
(86) PCT No.: PCT/IB11/00299

§ 371 Date: Aug. 7, 2012

(30) Foreign Application Priority Data
Feb. 18, 2010 (JP) 2010-033949

(51) Int. Cl. C30B 19/08

(52) U.S. Cl. 117/56

(57) ABSTRACT

A method of producing an SiC single crystal is provided in which an SiC single crystal is grown on a first seed crystal held at a lower end of a seed crystal holder, by immersing the first seed crystal in a source material melt in a crucible; this method of producing an SiC single crystal is characterized by carrying out a treatment that promotes the growth of a polycrystal in a region outside the first seed crystal.

### BACKGROUND OF THE INVENTION

1. Field of the Invention

The invention relates to a method of producing silicon carbide (SiC) single crystals by a so-called solution method.

2. Description of the Related Art

SiC is a semiconductor that exhibits excellent properties, for example, it has a band gap approximately three times that of silicon (Si) and its dielectric breakdown field strength is approximately 10 times that of Si, and its application to power devices makes possible the realization of devices that exhibit a lower power loss than Si power devices. In addition, SiC power devices not only provide a lower power loss than Si power devices, but are also capable of a higher temperature and faster operation than Si power devices. As a consequence, higher efficiencies and smaller sizes can be achieved for electric power conversion devices, e.g., inverters and so forth, through the use of SiC power devices.

Sublimation methods and solution methods are available for the production of SiC single crystal.

In solution methods, a seed crystal is immersed in a melt in which the source material is dissolved, and the source material dissolved in the melt around the seed crystal is brought into a supersaturated state—for example, by establishing a temperature gradient in which the temperature declines moving from within the melt toward the surface of the melt—and is thereby precipitated on the seed crystal. It has been reported that the micropipes present in the seed crystal are extinguished by the growth process in SiC single crystal production by solution methods. A crucible formed of graphite is generally used in SiC single crystal production by solution methods, and an Si melt is supplied with carbon (C), which is the other source material for SiC single crystals, from the graphite crucible. As a consequence, the carbon concentration in the melt is naturally at its maximum in the vicinity of the wall of the graphite crucible. In addition, the melt surface also has an interface with the atmospheric gas, and as a result the maximum temperature gradient is prone to occur in the vicinity of the melt surface. Accordingly, the carbon concentration assumes a supersaturated state at the melt surface in the vicinity of the wall of the graphite crucible, which sets up a tendency for coarse SiC crystals (referred to below as polycrystal) to be prone to precipitate. When, for example, this polycrystal adheres to the seed crystal and in its vicinity during growth, this creates the risk of inhibiting single crystal growth from the seed crystal, which is the original purpose. As a consequence, this polycrystal precipitation is a major problem for single crystal growth by a solution method.

Japanese Patent Application Publication No. 7-69779 (JP-A-7-69779) describes a single crystal pulling apparatus in which a crucible is disposed in a chamber, the interior of the crucible is divided into an inner region and an outer region by a cylindrical partition wall, and a single crystal is grown while continuously feeding a particulate source material into a melt of a single crystal source material in the outer region of the crucible. A cylindrical body that concentrically surrounds the single crystal during growth extends downward from the upper region of the chamber, and there is attached at the lower end of this cylindrical body a heat-insulating ring that has the shape of a truncated cone that tapers in the downward direction. This single crystal pulling apparatus is characterized in that the shell of this heat-insulating ring is composed of a carbon material and the interior of this shell is filled with a heat-insulating material. JP-A-7-69779 further states that, because the described single crystal pulling apparatus can maintain a high temperature in the vicinity of the interface between the partition wall and the melt surface, solidification of the melt in the vicinity of the partition wall can be prevented, the single crystal growth rate can be raised, and an improved productivity can then be obtained.

Japanese Patent Application Publication No. 2009-274887 (JP-A-2009-274887) describes a method of producing an SiC single crystal by growing an SiC single crystal on an SiC seed crystal from a silicon-chromium-carbon (Si—Cr—C) solution of C dissolved in an Si—Cr melt, the method being characterized in that a direct-current magnetic field is applied to the Si—Cr—C solution.

An apparatus for producing SiC single crystal by a solution method is described in Japanese Patent Application No. 2009-030327 (JP-A-2009-030327). This apparatus is provided with a crucible that holds an Si-containing melt and that is disposed via an interposed heat-insulating material in a growth furnace; an external heating apparatus that is disposed around the growth furnace and that has a high-frequency coil for heating the melt and maintaining a prescribed temperature; a vertically displaceable carbon rod; and a seed crystal at the tip of this carbon rod. The side surface of the lower end of the carbon rod is provided with a region that inhibits the production of polycrystal; this region has a lower wettability by the melt than does the carbon rod.

A method of producing a single crystal by a solution method is described in Japanese Patent Application No. 2009-256222. This method is characterized by the use of a shaft that is provided with a cooling region that cools a seed crystal and a heating region that heats the shaft circumference and by growing the single crystal after contact between the seed crystal and solution by heating the shaft circumference while cooling the seed crystal.

### SUMMARY OF THE INVENTION

In the single crystal pulling apparatus described in JP-A-7-69779, the heat-insulating ring is disposed in a position whereby its lower end is at least 10 mm from the surface of the melt. Accordingly, even when SiC single crystal production is carried out using this apparatus, polycrystal precipitates in the vicinity of the inner wall of the graphite crucible and as a consequence the adherence of polycrystal at the seed crystal and in its vicinity cannot be adequately prevented.

JP-A-2009-274887 states that the production of a polycrystal layered material is effectively inhibited by the application of the direct-current magnetic field to the Si—Cr—C melt. However, it is quite difficult even with the method described in JP-A-2009-274887 to completely suppress the production of this polycrystal layered material.

The invention provides a method of producing SiC single crystal that, through its novel structure, can prevent polycrystal from adhering to the seed crystal and in its vicinity.

An aspect of the invention relates to a method of producing an SiC single crystal. This method includes growing an SiC single crystal on a first seed crystal held at a lower end of a seed crystal holder, by immersing the first seed crystal in a source material melt in a crucible; and carrying out a treatment that promotes a growth of a polycrystal in a region outside the first seed crystal.

The treatment that promotes the growth of the polycrystal in the method according to this aspect may includes a treatment that forms a temperature gradient exhibiting a temperature decline from the interior of the source material melt to the liquid surface of the source material melt and a temperature decline from the interior of the source material melt to the bottom of the crucible.

The treatment that promotes the growth of the polycrystal in the method according to this aspect may include a treatment of growing a polycrystal on a graphite material by immersing the graphite material in the free surface of the source material melt, and the graphite material that is immersed in the source material melt may be provided with a second seed crystal, and moreover the treatment that promotes the growth of the polycrystal may include a treatment of growing a polycrystal on the second seed crystal by immersing the second seed crystal in the free surface of the source material melt.

The treatment that promotes the growth of the polycrystal in the method according to this aspect may include a treatment that brings about growing a polycrystal on a third seed crystal by disposing the third seed crystal at least either at the bottom surface of the inner wall of the crucible or in a region of contact between the inner wall of the crucible and the liquid surface of the source material melt.

The graphite material in the method according to this aspect may be a graphite rod or a graphite ring.

The treatment that promotes the growth of the polycrystal in the method according to this aspect may include a treatment of growing a polycrystal on a textured region disposed on the inner wall surface of the crucible.

The textured region may have a surface roughness of more than 2.0 μm in the method according to this aspect.

The polycrystal may be formed of SiC in the method according to this aspect.

The temperature of the source material melt may be equal to or higher than 1800° C., and equal to or lower than 2300° C. in the method according to this aspect and may be equal to or less than 2000° C. in the method according to this aspect.

Because in the method according to the invention polycrystal precipitates and grows in a region outside the seed crystal for growing the SIC single crystal and outside the vicinity of this seed crystal, the adherence of polycrystal at the seed crystal and its vicinity can be substantially suppressed. As a consequence, the method of the invention makes possible the stable growth of an SiC single crystal either with little incorporation of polycrystal or with substantially no incorporation of polycrystal.

### BRIEF DESCRIPTION OF THE DRAWINGS

The foregoing and further objects, features, and advantages of the invention will become apparent from the following description of embodiments with reference to the accompanying drawings, wherein like numerals are used to represent like elements and wherein:

FIG. 1 is a cross-sectional drawing that schematically shows an example of an SiC single crystal production apparatus;

FIG. 2 is a cross-sectional partial drawing that schematically shows an example of an SiC single crystal production apparatus that is provided with a graphite material;

FIG. 3 is a graph that shows the temperature distribution in the source material melt of Example 1;

FIG. 4 is a photograph of the SiC single crystal obtained in Example 1;

FIG. 5 is a graph that shows the temperature distribution in the source material melt of Comparative Example 1; and

FIG. 6 is a photograph of the crystal obtained in Comparative Example 1.

### DETAILED DESCRIPTION OF EMBODIMENTS

The method of producing an SiC single crystal according to the embodiments of the invention is an SiC single crystal production method in which an SiC single crystal is caused to grow on a first seed crystal, i.e., a seed crystal for inducing the growth of the SiC single crystal, that is held at the lower end of a seed crystal holder, by immersing the first seed crystal in a source material melt in a crucible, wherein a treatment is performed that promotes the growth of polycrystal in a region outside the first seed crystal.

The inventor discovered that the precipitation and adherence of polycrystal at the seed crystal and its vicinity can be substantially inhibited by carrying out a treatment that promotes the growth of polycrystal in a region outside the seed crystal for growing the SiC single crystal and outside the vicinity of this seed crystal. In this Specification, “seed crystal and its vicinity” denotes, inter alia, the seed crystal itself, the surrounding melt surface, and the lower end of the seed crystal holder that holds the seed crystal.

While not intending to be bound by any particular theory, it is thought that, by promoting the growth of polycrystal in a region outside the seed crystal and its vicinity, the carbon concentration in the source material melt and particularly in the source material melt in the vicinity of the seed crystal can be lowered. Accordingly, it is thought that, because the carbon dissolved in the source material melt in this region can be prevented from attaining a supersaturated condition, or, put differently, because the carbon concentration in the source material melt in this region can be put into a nonsaturated state, the precipitation and adherence of polycrystal at the seed crystal and its vicinity are inhibited as a result. The related art for producing SiC single crystal by solution methods includes various proposals from the perspective of inhibiting the precipitation of polycrystal itself. Accordingly, it is very unexpected and should be regarded as surprising that the stable growth of an SiC single crystal on a seed crystal can be achieved, as in the method according to the embodiments of the invention, by promoting the growth of polycrystal in a region outside the seed crystal and its vicinity.

According to the method according to the embodiments of the invention, any treatment that can bring about the growth of polycrystal in a region outside the seed crystal and its vicinity can be employed as the treatment that promotes polycrystal growth. Examples of a “treatment that promotes polycrystal growth” in the method according to the embodiments of the invention are described below with reference to the drawings.

According to a first embodiment of the invention, a temperature gradient is formed in which the temperature declines moving from the interior of the source material melt toward the liquid surface of the source material melt and the temperature declines moving from the interior of the source material melt toward the bottom of the crucible.

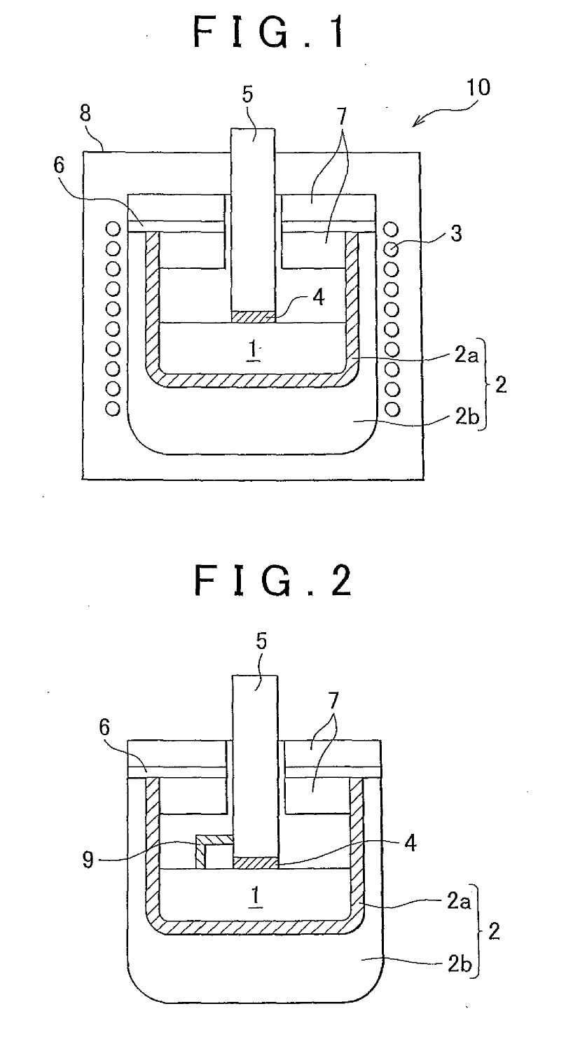

FIG. 1 is a cross-sectional drawing that schematically shows an example of an SiC single crystal production apparatus according to this embodiment.

With reference to FIG. 1, an SiC single crystal production apparatus 10 is provided with a crucible 2 for holding a source material melt 1 that forms the source material for the SiC single crystal, a heating means 3 that is disposed on the circumference of the crucible 2, a vertically displaceable seed crystal holder 5 that is disposed in the upper region of the crucible 2 and that has a seed crystal 4 at its lower end, an optional cover 6 for the crucible 2, and an optional heat-insulating material 7 that is disposed on both sides of the cover 6. More particularly, the crucible 2 is formed of an inner crucible 2a on the inner side of the crucible and an outer crucible 2b that is a susceptor region that holds the inner crucible 2a. In addition, in order to prevent chemical reactions between the atmospheric gas and the SiC single crystal product during SiC single crystal production using this SiC single crystal production apparatus 10, the crucible 2, heating means 3, and so forth are disposed in a chamber 8 and the interior of this chamber 8 is filled with an inert gas, for example, argon.

To produce an SiC single crystal using the SiC single crystal production apparatus 10, for example, a melt starting material is first introduced into the crucible 2; the interior of the chamber 8 is evacuated; and the interior of the chamber 8 is thereafter pressurized with an inert gas, e.g., argon, to atmospheric pressure or a pressure above atmospheric pressure. The crucible 2 is then heated by the heating means 3 to melt the melt starting material and form a source material melt 1. The seed crystal holder 5 is subsequently brought downward from above the liquid surface of the melted source material melt 1 in order to bring the seed crystal into contact with the liquid surface of the source material melt 1. After this, for example, an SiC single crystal is formed on the seed crystal by pulling the seed crystal holder 5 upward while, for example, slowing rotating the seed crystal holder 5.

As previously noted, a crucible formed of graphite is ordinarily used for the production of SiC single crystal by solution methods, and carbon (C), which is the other source material for the SiC single crystal, is supplied from this graphite crucible into an Si melt. Accordingly, a high carbon concentration typically occurs at the surface of the source material melt in the vicinity of the inner wall of the crucible, and as a consequence coarse SiC crystals, i.e., polycrystal, are prone to precipitate in the region of contact between the crucible inner wall and the surface of the source material melt. By establishing, in accordance with the embodiment under consideration, a temperature gradient in which the temperature declines moving from the interior of the source material melt to the liquid surface of the source material melt, the generally high carbon concentration in this region can be brought into a more supersaturated state and the precipitation and growth of polycrystal in this region can as a consequence be promoted.

In addition, by establishing a temperature gradient in which the temperature declines moving from the interior of the source material melt to the bottom of the crucible, the carbon concentration in the source material melt can also be brought into a supersaturated state at the bottom inner wall region of the crucible, and as a consequence the precipitation and growth of polycrystal at the bottom inner wall of the crucible can be substantially promoted—just as for the region of contact between the inner wall of the crucible and the surface of the source material melt.

According to the first embodiment of the invention, as described in the preceding the precipitation and growth of polycrystal can be substantially promoted in a region outside the seed crystal and its vicinity and particularly in the region of contact between the inner wall of the crucible and the surface of the source material melt and at the bottom of the inner wall of the crucible. As a result, the carbon concentration in the source material melt is lowered in the vicinity of the seed crystal, i.e., the carbon dissolved in the source material melt in this region is prevented from assuming a supersaturated state, and, because of this, the precipitation and adherence of polycrystal at the seed crystal and its vicinity can be substantially inhibited.

The temperature of the source material melt in the production according to this example of SiC single crystal by a solution method should be a temperature that is equal to or greater than the melting point of the source material in order to keep the source material in a molten state, and a temperature of at least 1800° C. can generally be used. Since phenomena such as a pronounced evaporation of Si from the source material melt occur when the temperature of the source material melt exceeds 2300° C., the temperature of the source material melt generally is to be no more than 2300° C. and is preferably no more than 2000° C. Thus, in the first embodiment of the invention, a temperature gradient may be formed generally in the temperature range from 1800 to 2300° C. and preferably in the temperature range from 1800 to 2000° C. A temperature gradient may be formed in which the liquid surface of the source material melt assumes a temperature of 1800 to 2000° C. and the bottom of the inner wall of the crucible assumes a temperature of 1800 to 2000° C.

The temperature gradient described in the preceding may be generated, for example, by forming the heating means 3 disposed on the circumference of the crucible into two stages, i.e., an upper stage and a lower stage, and subjecting these two heating means to independent control. This temperature control may be performed, for example, by regulating the output from these two heating means based on the temperature of the source material melt as measured using a radiation thermometer or a thermocouple, e.g., a tungsten-rhenium (W—Re) thermocouple, inserted within the seed crystal holder and/or into the source material melt.

In a second embodiment of the invention, a graphite material is immersed in the free surface of the source material melt and/or a second seed crystal is disposed at the bottom surface of the inner wall of the crucible, or at the region of contact between the inner wall of the crucible and the liquid surface of the source material melt, or at both locations. The “free surface of the source material melt” in this embodiment refers to the liquid surface of the source material melt that is not in contact with the inner wall of the crucible, that is not in contact with the seed crystal holder, and that is not in contact with the first seed crystal held at the lower end of the seed crystal holder.

FIG. 2 is a cross-sectional partial drawing that schematically shows an example of an SiC single crystal production apparatus that is provided with the graphite material described above.

With reference to FIG. 2, one end of an L-shaped graphite material 9 is attached to a side surface of the seed crystal holder 5 and the other end of this graphite material 9 is immersed in the free surface of the source material melt. While one end of the graphite material 9 is attached to a side surface of the seed crystal holder 5 in FIG. 2, this end may be attached, for example, to the crucible 2 and specifically, e.g., to the inner wall of the inner crucible 2a.

The immersion of this graphite material in the free surface of the source material melt causes polycrystal that precipitates in the source material melt to adhere and grow on the graphite material. This results in a decline in the carbon concentration in the source material melt in the vicinity of the seed crystal; that is, because the carbon dissolved in the source material melt in this region is prevented from assuming a supersaturated state, the precipitation and adherence of polycrystal at the seed crystal and its vicinity can be substantially inhibited.

Any shape can be used for this graphite material and there are no particular limitations on its shape. For example, a rod-shaped graphite material as shown in FIG. 2 may be used or a ring-shaped graphite material may be used. When a ring-shaped graphite material (referred to below as a graphite ring) is employed, for example, the graphite ring may be attached to the one end of the graphite material 9 shown in FIG. 2 that is in contact with the source material melt. The disposition of a graphite ring around the first seed crystal in this manner makes possible a reliable and secure adherence and growth on the graphite ring of the polycrystal that precipitates in the source material melt, and as a consequence can substantially suppress the precipitation and adherence of polycrystal at the first seed crystal and its vicinity.

Moreover, this graphite material may be immersed by itself in the free surface of the source material melt, or may preferably be provided with a second seed crystal at the one end that is the region of contact with the source material melt. Due to the facile adherence by SiC nuclei when this is done, a further promotion of polycrystal precipitation and growth can be obtained over immersion of just the graphite material in the free surface of the source material melt.

In addition to or instead of attachment of this second seed crystal to the graphite material, a third seed crystal may be disposed on the bottom surface of the inner wall of the crucible or in the region of contact between the crucible inner wall and the liquid surface of the source material melt or at both locations. Since, as previously noted, carbon, which is one source material for the SiC single crystal, is supplied from the crucible, a high carbon concentration occurs in the source material melt in the vicinity of the crucible inner wall and polycrystal precipitation is therefore prone to occur in the vicinity of the crucible inner wall. Accordingly, by disposing a third seed crystal in this region, and particularly at the bottom surface of the inner wall of the crucible and/or in the region of contact between the crucible inner wall and the liquid surface of the source material melt, a substantial promotion of polycrystal precipitation and growth in these regions can be obtained.

As a modification of the second embodiment of the invention or in addition to this second embodiment, a temperature distribution may be formed in the source material melt whereby the crucible wall has a lower temperature. By doing this, the carbon concentration in the source material melt can be brought into a more supersaturated state in the vicinity of the crucible wall and particularly at the bottom surface of the crucible inner wall and the region of contact between the crucible inner wall and the liquid surface of the source material melt, and as a consequence an even greater promotion of polycrystal precipitation and growth in these regions can be obtained.

According to a third embodiment of the invention, a textured region is disposed on the crucible inner wall surface that is in contact with the source material melt.

This disposition of a textured region in the crucible inner wall surface results in a large area of contact between the crucible inner wall surface and the source material melt and as a consequence can increase the quantity of carbon that dissolves from the crucible into the source material melt. Polycrystal precipitation and growth in this textured region can be promoted as a result.

This textured region may be any textured region that can provide a large area of contact between the crucible inner wall surface and the source material melt and is not particularly limited; however, a textured region having, for example, a surface roughness Ra in excess of 2.0 μm is preferred. The “surface roughness Ra” in this invention denotes the arithmetic mean roughness specified in JIS B 0601. When the textured region has a surface roughness Ra of 2.0 μm or less, a satisfactory effect may not be obtained with regard to increasing the quantity of carbon dissolving from the crucible into the source material melt.

This textured region can be disposed at any location on the crucible inner wall surface that is in contact with the source material melt and there is no particular limitation here; however, a textured region is preferably disposed, for example, on the bottom surface of the crucible inner wall and/or in the region of contact between the crucible inner wall and the liquid surface of the source material melt. Since, as noted above, these regions—and particularly the region of contact between the crucible inner wall and the liquid surface of the source material melt—are regions in which polycrystal is prone to precipitate, the disposition of a textured region in such regions can further promote polycrystal precipitation and growth.

The individual embodiments described in the preceding may be implemented individually or combinations of them may be implemented.

As previously noted, in each of the embodiments of the invention, in order to prevent the adherence of polycrystal at the seed crystal and its vicinity, the carbon concentration is prevented from assuming a supersaturated state in the source material melt and particularly in the source material melt around the seed crystal. In the production of SiC single crystal by solution methods, a temperature gradient sufficient to induce the growth of the SiC single crystal from the seed crystal generally must be produced at the contact interface between the seed crystal and the source material melt. Accordingly, in the method according to each of the embodiments of the invention, a temperature gradient sufficient to induce the growth of the SiC single crystal from the seed crystal may be produced at the contact interface between the seed crystal and the source material melt by, for example, lowering only the temperature at this contact interface by suitable cooling of the seed crystal itself.

Any method available to the individual skilled in the art may be used as the method for cooling the seed crystal itself in each of the previously described embodiments, and there is no particular limitation here. As an example, a method may be used in which the seed crystal holder, which holds the seed crystal and is formed of, for example, graphite, is attached at the lower end of a tube that has a double tube structure and is formed of, for example, stainless steel or Mo, and the seed crystal held at the lower end of the seed crystal holder is cooled by flowing water or a gas at a prescribed flow rate from the inner tube into the outer tube of the double tube.

Since the quantity of carbon that dissolves in the Si melt from the graphite crucible is very small in the production of SiC single crystal by solution methods, a satisfactory SiC single crystal growth rate may not be obtained in some instances. As a consequence, in order to raise the SiC single crystal growth rate, an element such as, for example, titanium (Ti), manganese (Mn), Cr, or aluminum (Al), may optionally be added in a prescribed quantity to the source material melt in SiC single crystal production by the method according to each embodiment of the invention.

In addition, either one or both of the crucible and seed crystal holder, for example, may optionally be rotated in order to bring about uniform SiC single crystal growth in SiC single crystal production by the solution method according to each of the previously described embodiments. This rotation may be a constant rotation or a variable rotation. Moreover, the direction of crucible rotation may be the same as or opposite from the direction of seed crystal holder rotation. Their rotation rates, rotation directions, and so forth may be suitably determined in conformity to, for example, the operating conditions for the SiC single crystal production apparatus.

Examples of the invention are described in detail in the following.

### EXAMPLE 1

In this example, the production of SiC single crystal by a solution method was performed using the SiC single crystal production apparatus shown in FIG. 1, and the effect was examined for the implementation of a treatment that promoted polycrystal growth in a region outside the seed crystal. The experimental conditions are given below.

### Experimental Conditions

initial composition of the source material melt: Si/Ti/Al=70/20/10 (at %)

high-frequency coil outputs: upper stage coil/lower stage coil=30/50 (kW)

high-frequency coil frequencies: upper stage coil/lower stage coil=20/8 (kHz)

high-frequency coil current values: upper stage coil/lower stage coil=291.6/356.0 (A)

high-frequency coil current value ratio: upper stage coil : lower stage coil=1:1.22

seed crystal: on-axis n-type 4H—SiC (0001)

seed crystal holder: isotropic graphite shaft

pressure: argon (Ar) atmosphere, 30 kPa (gauge pressure)

growing time: 10 hours

crucible: graphite crucible (inner diameter=150 mm)

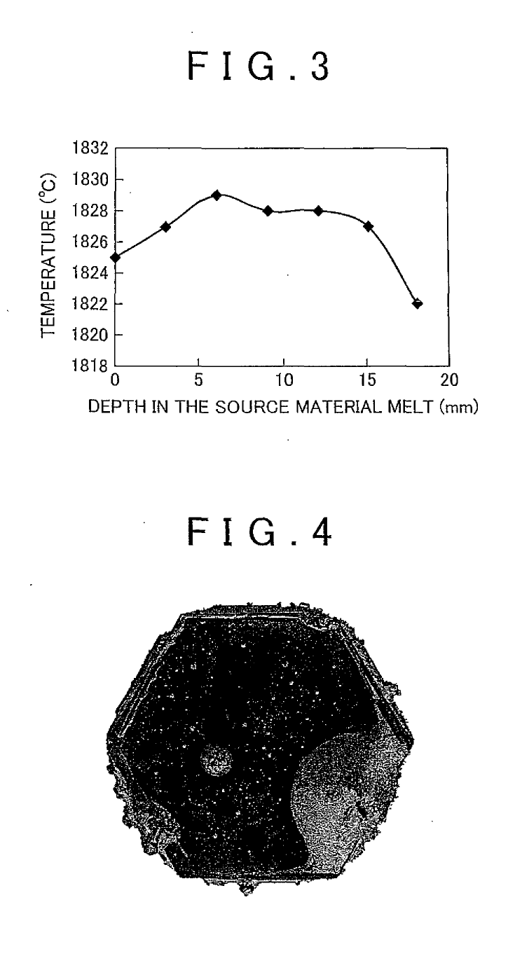

temperature conditions: refer to FIG. 3

The production of SiC single crystal by the solution method described above was carried out using the accelerated crucible rotation technique (ACRT). Specifically, the following process was repeated for 10 hours: the seed crystal holder was rotated at 50 rpm and the crucible was rotated in the same direction at 5 rpm, for example, clockwise rotation was carried out for 45 seconds; this was followed by stoppage for 20 seconds; then, rotation was carried out in the opposite direction at the same rotation rates as before, respectively, for example, for 45 seconds in the counterclockwise direction; and this was followed by stoppage for 20 seconds. The seed crystal holder used in this example was attached at the lower end of a double tube, for example, of stainless steel or molybdenum (Mo), and the seed crystal held at the lower end of the seed crystal holder was cooled by running 25° C. water at a flow rate of 12 L/minute from the inner tube of the double tube into its outer tube. The liquid surface of the source material melt was set to agree with the middle of the full length of the high-frequency coil formed of the upper stage coil and the lower stage coil, and the total depth from the liquid surface of the source, material melt to the bottom surface of the crucible inner wall was approximately 32 to 33 mm. The temperature distribution shown in FIG. 3 for the source material melt is based on the results of measurement of the temperature at each depth point in the source material melt using W—Re thermocouples inserted in graphite protecting tubes.

A photograph of the SiC single crystal obtained in Example 1 is shown in FIG. 4. The grey region on the lower right in FIG. 4 is source material melt from within the crucible that adhered and crystallized on the produced SiC single crystal when this SiC single crystal was pulled up from the source material melt. As is clear from the photograph in FIG. 4, a crystal habit originating in the same hexagonal crystal structure as the seed crystal was seen for the obtained SiC single crystal, and there was almost no incorporation of spurious crystals (polycrystal). In addition, there was a particularly substantial deposition of SiC polycrystal on the side and bottom surfaces of the crucible inner wall after SiC single crystal production in Example 1. These results demonstrated that the method according to this example of the invention could provide a substantial promotion of polycrystal precipitation and growth in regions outside the seed crystal and its vicinity and particularly in, inter alia, the side surface of the crucible inner wall and the bottom surface of the crucible inner wall, and as a result could suppress the precipitation and adherence of polycrystal at the seed crystal and its vicinity and could bring about the stable growth of an SiC single crystal that was substantially free of polycrystal incorporation.

### Comparative Example 1

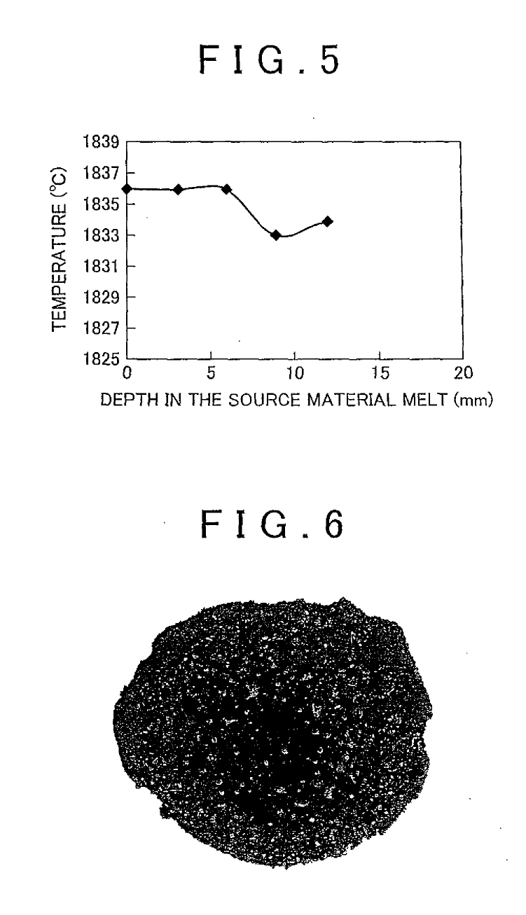

An SiC single crystal was produced by a solution method in this comparative example in the same manner as in Example 1, with the exception that the temperature distribution in the source material melt was regulated as shown in FIG. 5 and a growing time of 5 hours was used. The particular experimental conditions for Comparative

Example 1 are given below.

### Experimental Conditions

initial composition of the source material melt: Si/Ti/Al=70/20/10 (at %)

high-frequency coil outputs: upper stage coil/lower stage coil=30/50 (kW)

high-frequency coil frequencies: upper stage coil/lower stage coil=20/8 (kHz)

high-frequency coil current values: upper stage coil/lower stage coil=303.1/356.0 (A)

high-frequency coil current value ratio: upper stage coil : lower stage coil=1:1.17

seed crystal: on-axis n-type 4H—SiC (0001)

seed crystal holder: isotropic graphite shaft

pressure: Ar atmosphere, 30 kPa (gauge pressure)

growing time: 5 hours

crucible: graphite crucible (inner diameter=150 mm)

temperature conditions: refer to FIG. 5

A photograph of the crystal obtained in Comparative Example 1 is shown in FIG. 6. Referring to FIG. 6, unlike the situation in Example 1, a crystal habit originating in the same hexagonal crystal structure as the seed crystal was not seen for the obtained crystal, and a large amount of spurious crystal (polycrystal) incorporation was observed.

While some embodiments of the invention have been illustrated above, it is to be understood that the invention is not limited to details of the illustrated embodiments, but may be embodied with various changes, modifications or improvements, which may occur to those skilled in the art, without departing from the scope of the invention.

1. A method for producing an SiC single crystal, characterized by comprising:
growing an SiC single crystal on a first seed crystal held at a lower end of a seed crystal holder, by immersing the first seed crystal in a source material melt in a crucible; and
carrying out a treatment that promotes a growth of a polycrystal in a region outside the first seed crystal.

2. The method according to claim 1, wherein the treatment that promotes the growth of the polycrystal includes a treatment that forms a temperature gradient exhibiting a temperature decline from the interior of the source material melt to the liquid surface of the source material melt and a temperature decline from the interior of the source material melt to the bottom of the crucible.

3. The method according to claim 1 or 2, wherein the treatment that promotes the growth of the polycrystal includes a treatment of growing a polycrystal on a graphite material by immersing the graphite material in the free surface of the source material melt.

4. The method according to claim 3, wherein the graphite material that is immersed in the source material melt is provided with a second seed crystal, and the treatment that promotes the growth of the polycrystal includes a treatment of growing a polycrystal on the second seed crystal by immersing the second seed crystal in the free surface of the source material melt.

5. The method according to any one of claims 1 to 4, wherein the treatment that promotes the growth of the polycrystal includes a treatment that brings about growing a polycrystal on a third seed crystal by disposing the third seed crystal at least one of at the bottom surface of the inner wall of the crucible, in a region of contact between the inner wall of the crucible, and the liquid surface of the source material melt.

6. The method according to claim 5, wherein the graphite material is a graphite rod or a graphite ring.

7. The method according to any one of claims 1 to 6, wherein the treatment that promotes the growth of the polycrystal includes a treatment of growing a polycrystal on a textured region that is disposed on the inner wall surface of the crucible.

8. The method according to claim 7, wherein the textured region has a surface roughness of more than 2.0 μm.

9. The method according to any one of claims to 8, wherein the polycrystal is formed of SiC.

10. The method according to any one of claims 1 to 9, wherein a temperature of the source material melt is equal to or higher than 1800° C., and equal to or lower than 2300° C.

11. The method according to claim 10, wherein the temperature of the source material melt is equal to or less than 2000° C.
